(19) United States
(12) Patent Application Publication
(10) Pub. No.: US 2005/0281014 A1
(43) Pub. Date: Dec. 22, 2005

(54) Surrogate card for printed circuit board assembly

(76) Inventors: Thomas J. Carullo, Marlton, NJ (US); Arthur G. Willers, Delran, NJ (US)

Correspondence Address: BECK AND TYSVER P.L.L.C., 2900 THOMAS AVENUE SOUTH, SUITE 100, MINNEAPOLIS, MN, 55416, US

(21) Appl. No.: 10/873,377

(22) Filed: Jun. 21, 2004

(51) Int. Cl. H05K 7/14

(52) U.S. Cl. 361/796

(57) ABSTRACT

A surrogate card assembly is configured to mimic the profile of a printed circuit board. The surrogate card assembly takes the place of a printed circuit board in an array of boards in a chassis or housing and mimics the active printed circuit boards with respect to directing air flow and providing EMC shielding.

### FIELD OF THE INVENTION

The present invention relates generally to a surrogate card to replace or stand in for a printed circuit board assembly in an array of boards supported in a housing or chassis.

### BACKGROUND OF THE INVENTION

It is common to house a number of printed circuit board assemblies together in a chassis. The chassis, or a tray structure within the chassis, supports an array of boards in predefined, spaced-apart positions. It is further typical that the circuit boards are individually removable to allow the necessary flexibility in achieving the operation desired of the confluence of printed circuit board assemblies. Thus, designated spaces for a printed circuit board may intentionally be left open or empty.

Heat management within such a chassis is important because, when powered, the printed circuit boards generate heat, as do components typically included in the chassis to support the operation of the circuit boards, such as one or more power supplies. This heat can interfere with performance of the boards individually and the assembly as a whole. Typically, fans are used to move air in a desired manner through the chassis and past the circuit boards to cool them.

Air flow through the chassis is affected by the number and arrangement of boards that are inserted in the chassis. In particular, each printed circuit board, during operation, blocks a certain amount of air flow, thus causing the air flow to be distributed more evenly across all other printed circuit boards in the chassis. When a board is left out, a disproportionate amount of air bypasses the remaining active printed circuit boards assemblies raising the potential for overheating and problems associated therewith.

Another concern in a chassis holding printed circuit boards is electromagnetic compliance (EMC) shielding. When a printed circuit board is removed or uninstalled, the vacancy yields large unattended openings that negatively effects air flow and electromagnetic containment.

### SUMMARY OF THE INVENTION

A surrogate or dummy card takes the place of a printed circuit board in a chassis having predetermined slots or locations for printed circuit boards. The surrogate card mimics the effect of a printed circuit board on air flow through the chassis. Further, the surrogate card mimics an active printed circuit board assembly in regard to electromagnetic compliance shielding.

### BRIEF DESCRIPTION OF THE DRAWINGS

An exemplary version of a surrogate card is shown in the figures wherein like reference numerals refer to equivalent structure throughout, and wherein:

FIG. 1 is an exploded perspective view of a portion of a chassis, printed circuit boards to be placed in the chassis, and a surrogate card assembly to stand in for a printed circuit board in the chassis;

FIG. 2 is an end view of the chassis of FIG. 1 with an array of printed circuit boards in position; and

FIG. 3 is an exploded perspective view of a portion of the chassis of FIG. 1, taken from the opposite end from that of FIG. 1;

FIG. 4a is a schematic perspective view of a printed circuit board like that shown in FIG. 1;

FIG. 4b is a schematic top view of a printed circuit board of FIG. 4a;

FIG. 5 is an enlarged perspective view of a surrogate card assembly like that shown in FIG. 1;

FIG. 6 is an enlarged perspective view of the opposite face of the surrogate card assembly of FIG. 5; and

FIG. 7 is an exploded view of the surrogate card assembly of FIGS. 5 and 6.

### DETAILED DESCRIPTION OF PREFERRED EMBODIMENT(S)

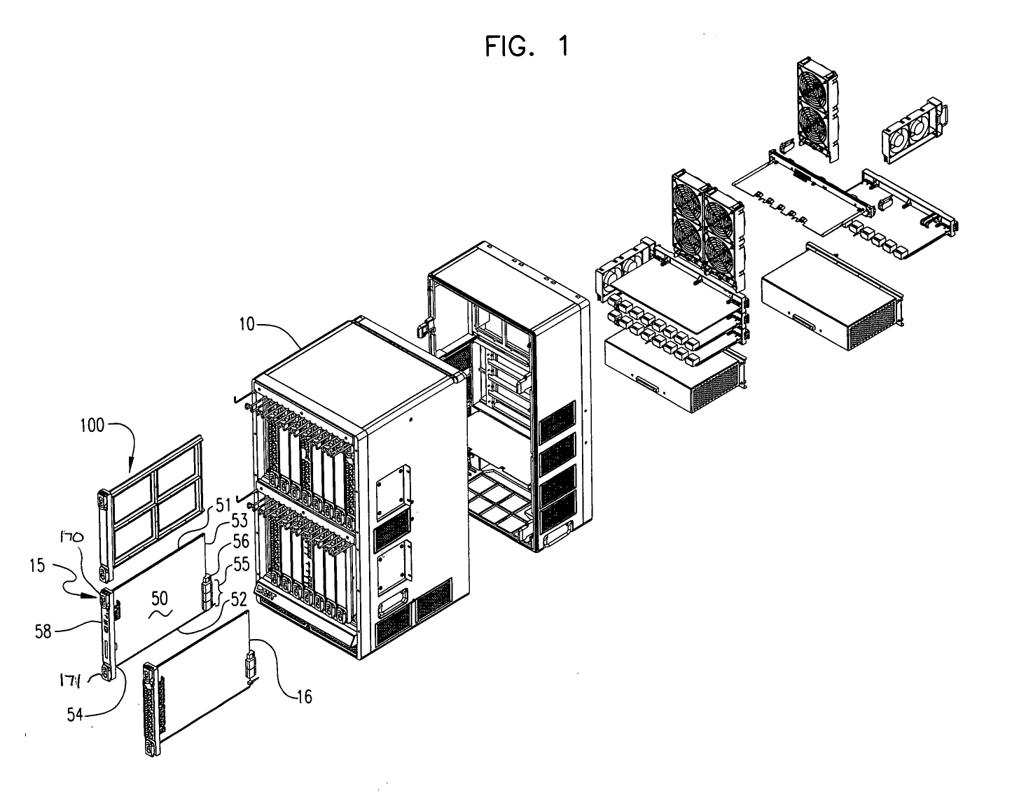

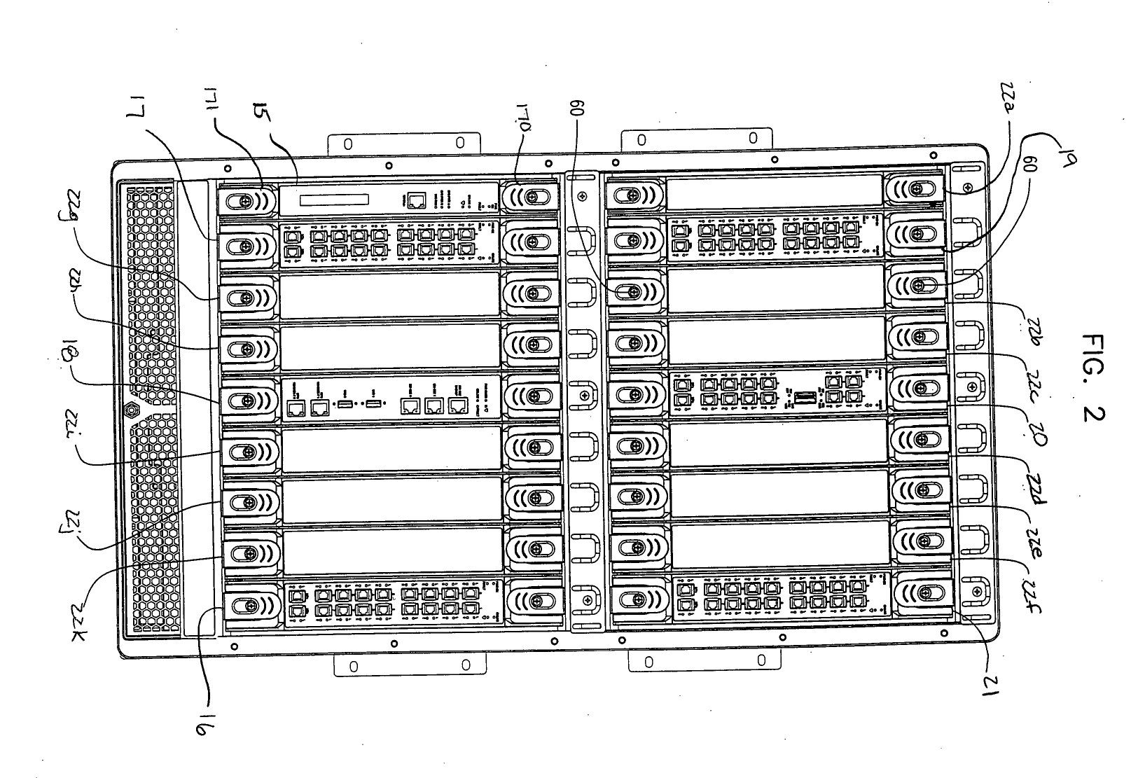

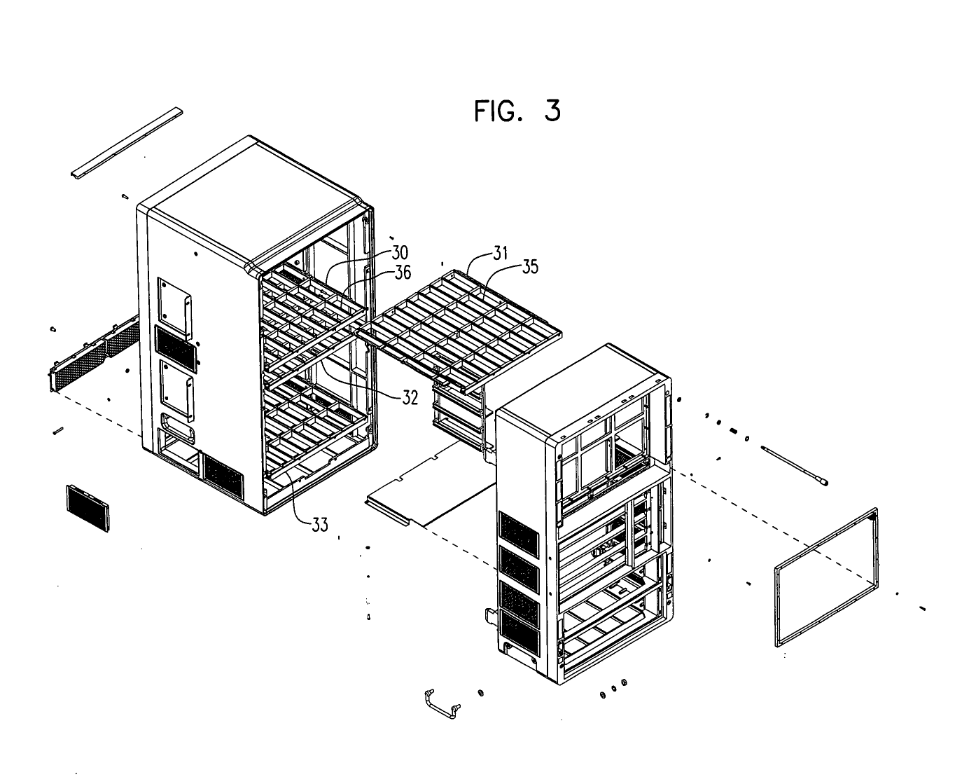

FIGS. 1 and 2 illustrate a portion of a chassis 10 for housing several printed circuit board assemblies, such as representative assemblies indicated by reference numbers 15 and 16. The chassis 10 defines slots, or includes trays 30-33 that define slots, for receiving and supporting the PCB assemblies (See FIG. 2) as illustrated in FIG. 3. More specifically, an aligned pair of slots (for example slots 35, 36) receives and supports opposite edges of a circuit board assembly 15. The portion of the chassis 10 illustrated includes slots or predetermined positions for eighteen (as viewed in FIG. 2) possible printed circuit board assemblies or surrogate cards, but it will be understood that the surrogate card described herein can be advantageously used in conjunction with a housing having any number of positions for printed circuit board assemblies. In the embodiment illustrated, the chassis 10 is housing seven active printed circuit board assemblies 15, 16, 17, 18, 19, 20, 21 and eleven surrogate assemblies 22a-k.

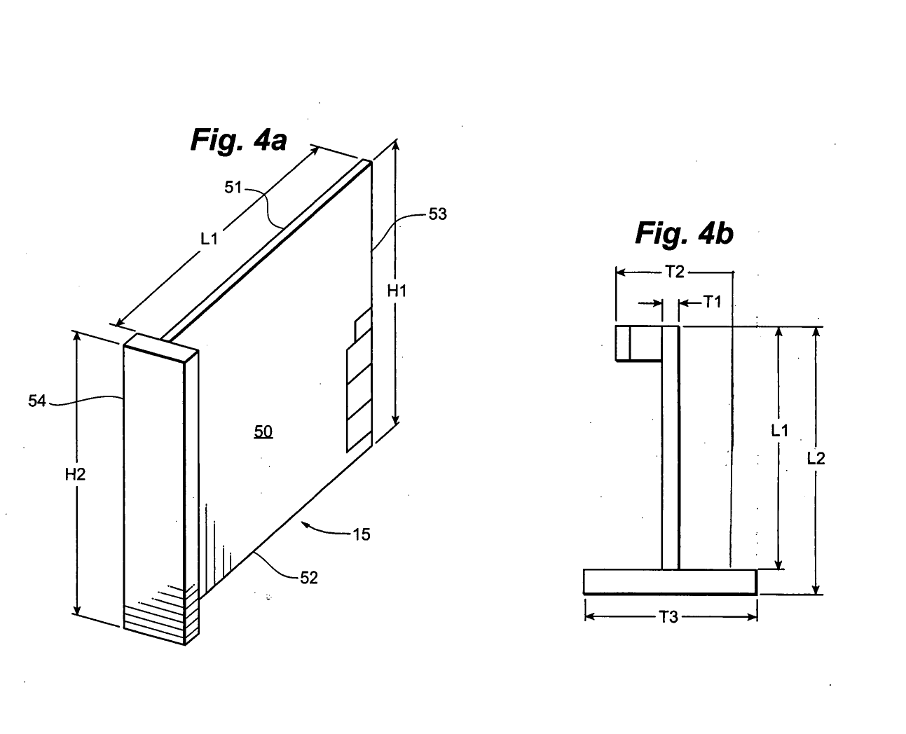

The structure of the printed circuit board assemblies will be described with reference to the printed circuit board assembly designated by reference number 15, pictured in FIGS. 1 and 4. The printed circuit board assembly 15 includes a printed circuit board 50 which is a generally planar, rectangular member having circuit components (not shown) printed on or attached to the board 50 on one or both faces. The board 50 has generally four edges: top 51, bottom 52, first side 53, second side 54. Here and throughout this application, words that suggest a particular orientation, such as “top”, “bottom”, and “side” are used merely for convenient reference and are not intended to be limiting. It should be understood that components may be oriented in alternative manners within the scope of this invention.

Connectors 55 along one side edge 53 of the printed circuit board assembly 15 connect the printed circuit board to other components to allow data transfer therebetween. A power connector 56 along a side edge 53 connects the board 50 to a power source, directly or indirectly. The connectors 55 and 56 also establish a friction fit with mating connectors.

A face plate 58 mounts to a printed circuit board and is used for convenient handling of the assembly 15 without unduly touching the printed circuit board 50. The face plate 58 includes handles or tabs or latches 170, 171 and receive a screw 60 to secure the assembly 15 to the chassis 10, as shown in FIG. 2. The operation of handles 170 will be described below

When the assembly 15 is mounted in the chassis 10, the face plate 58 remains accessible from the outside of the chassis 10, to allow the assembly 15 to be easily removed, as shown in FIG. 1. For EMC shielding, an EMC gasket (not shown) resides along the perimeter of the face plate 58 where the face plate 58 meets the surface of the chassis 10. With the gasket thus sandwiched between the face plate 58 and the chassis 10, a seal against leakage of electromagnetic energy is established.

Printed circuit boards and their assemblies may vary in size and shape. For reference, several dimensions are illustrated with respect to assembly 15 in FIGS. 4a and 4b. The generally rectangular printed circuit board 50 has a height H1, a length L1 and a thickness T1. The thickness T1 represents the thickness of the planar portion of the board 50. The thickness T2 represents the thickness of the circuit board 50 including the components (such as resistors, capacitors, etc, not shown; only a single connector 55 is illustrated) extending from the surface of the planar portion.

The words “length” and “height” are used merely for convenient reference to the pictured assembly 15 as oriented in FIGS. 1, 4a and 4b. The chassis 10 might instead provide for the boards to be positioned horizontally or at an angle, in which case the “height” might then be considered a width. Further, though the word “length” is used for the longer dimension of the pictured board 50, it should be understood that the length is not necessarily greater than the “height”.

The face plate is generally wider in the direction indicated by T3 than the thickness T2 of the printed circuit board. The height H2 of the face plate is generally a bit longer than the height H1 of the mating printed circuit board 50.

The many printed circuit board assemblies in a chassis typically vary from one to the next. Nevertheless, it is a typical chassis design to provide predetermined positions that are relatively uniform in size and are relatively uniformly spaced. For operation, various printed circuit boards are selected and inserted into the chassis based on the functions to be performed by the collection of boards in the chassis. For some applications, the chassis may contain positions for printed circuit boards that do not need to be used. Leaving a position empty compromises the operation of the array of boards in at least two respects: 1) air flow through the chassis is adversely affected by an empty slot because air flow through the chassis will not be distributed as evenly across the existing active printed circuit boards, leading to higher temperatures next to the boards and perhaps causing overheating; and 2) an empty or open position leaves a leak point for electromagnetic energy.

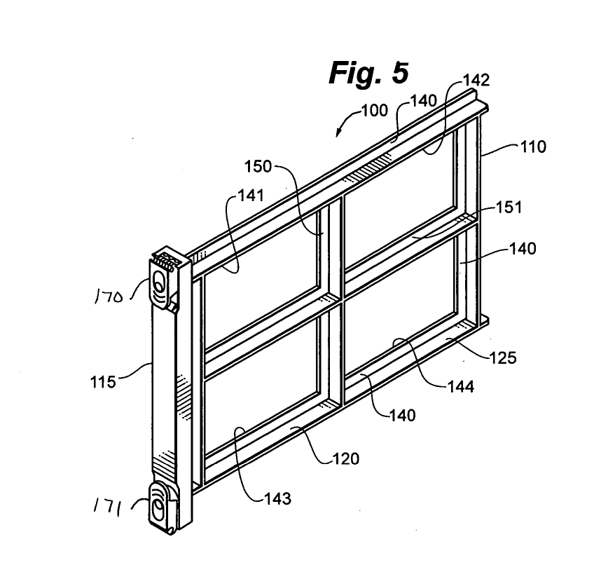

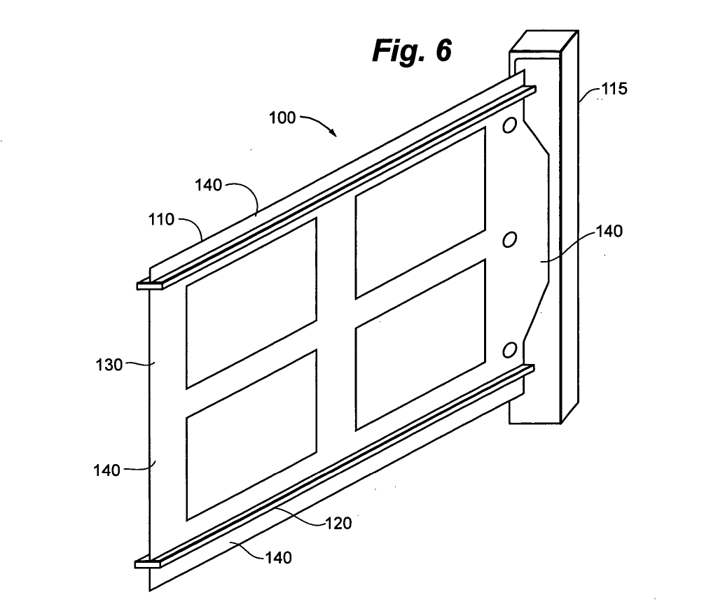

A surrogate card assembly 100, illustrated in FIGS. 1 and 5-7, resolves these issues. The surrogate card assembly 100 is sized and shaped to fill a position for a printed circuit board in the chassis 10. The surrogate card assembly 100 includes a frame 110 mounted to a face place 115. The frame is generally planar, with baffles 120 extending therefrom on both front and back surfaces. The front surface 125 is pictured in FIG. 5, and the back surface 130 is pictured in FIG. 6. In the embodiment illustrated, the frame 100 includes a perimeter frame portion 140 divided into generally four sections or windows 141, 142, 143, 144 by a vertical support section 150 that generally divides the length of the perimeter frame portion 140, and a horizontal support section 151 that generally divides the height of the perimeter frame portion 140. Terms such as “front”, “back”, “horizontal”, “vertical” are merely used for convenient reference to the orientation of the surrogate card assembly 100 as presented on the drawing page, but should not be considered limiting in any manner.

The frame 110 is preferably molded as a single integral piece of PC/ABS plastic approved by the Underwriters Lab for use with Electrical Equipment, UL 476, and UL Safety Specifications 60950, UL94-VO Fire retardancy rating. By defining windows within the frame 110, less material is used, reducing the manufacturing cost and decreasing the weight of the frame 110 and assembly 100.

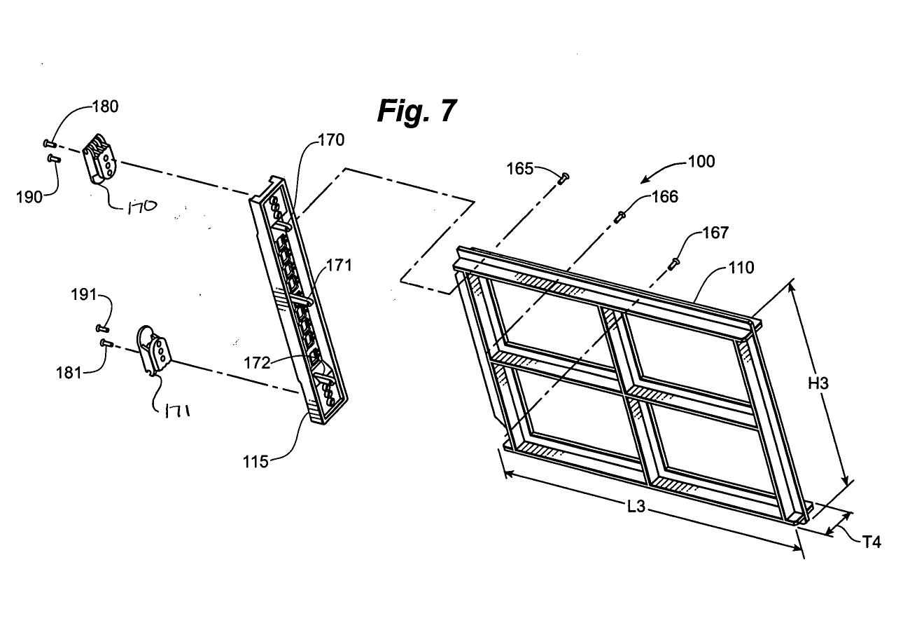

FIG. 7 illustrates an exploded view of the surrogate card assembly 100. The face plate 115 mounts on the frame 110 via screws 165, 166, 167 through the frame 110 and through flanges 170, 171, 172 on the face plate 115. EMC gaskets (not shown) are positioned behind the face plate 115, mounted on the chassis frame 10. When the face plate is positioned to the chassis frame 10, the perimeter of the face plate 115 seals against the gaskets on the chassis frame 10 performing a EMC seal to prevent electromagnetic energy from escaping from the chassis 10.

Handles 170, 171 attach to the face plate 115 via screws 180, 181. The handles 170, 171 are hinged, having pertrusions that frictionally engage the chassis when the handle is in a closed position and that release their connection when the handle is in an open position. Screws 190, 191 secure the handles 170, 171 in a closed position. In other words, the handles 170, 171 include structure that allows them to grip a lip or edge of the chassis in their closed position. Screws 190, 191 holds the handles 170, 171 in the closed position. When the screws 190, 191 are disengaged, the handles 170, 171 open and the gripping structure releases from the chassis.

The baffles 120 extend from the front and back surfaces 125, 130 such that the thickness T4 of the frame 110 approximates the thickness T2 of the active printed circuit boards in the chassis 10. Other dimensions of the frame 110 are indicated in FIG. 7. L3 represents the length of the frame 110; H3 represents the height of the frame 110. For surrogate card assembly 100 to replace printed circuit board 15, the length L3 of the frame 110 of the surrogate approximates L1 of the printed circuit board 15; and the height H3 of the surrogate approximates H1 of the board 15. Thus, the surrogate has approximately the same profile as the board 15 it replaces and distributes air as would the board 5 it replaces. In other words, the surrogate distributes air across the other boards in the chassis as would an active board 15, and the cooling system for the chassis is able to function as intended.

The chassis pictured in the figures is described in greater detail in the following applications, hereby incorporated by reference:

| | | | Atty |
|---|---|---|---|
| Title | Filing Date | USSN | Docket No. |
| Modular Chassis Divided Along | Jun. 21, 2004 | | 3045 |
| a Midplane and Cooling System | | | |
| Therefor | | | |
| Removable Ribs in a Chassis | Jun. 21, 2004 | | 3058 |
| Housing to Accommodate Extra- | | | |
| Wide Printed Circuit Board | | | |
| Assemblies | | | |

Although an illustrative version of the device is shown, it should be clear that many modifications to the device may be made without departing from the scope of the invention.

1. A surrogate card assembly for filling an empty predetermined position in an array of printed circuit boards housed in a chassis, comprising a generally planar frame having approximately the same profile as a printed circuit board.

2. A surrogate card assembly according to claim 1, having baffles extending outwardly from the planar frame.

3. A surrogate card assembly according to claim 2, wherein said baffles extend from the frame a distance that mimics the thickness of a printed circuit board.

4. A surrogate card assembly according to claim 2, wherein said baffles are perpendicular to said frame.

5. A surrogate card assembly according to claim 1 wherein said planar frame defines an opening.

6. A surrogate card assembly according to claim 5 wherein said planar frame includes a perimeter frame section and includes a support section extending from one side of the perimeter frame to another.

7. A surrogate card assembly according to claim 6 wherein said perimeter frame is rectangular and one support section divides one set of opposite sides of the rectangle and another support section divides the other set of opposite sides, yielding four openings defined by the planar frame.

8. A surrogate card assembly according to claim 7, wherein baffles extend outwardly from said perimeter frame and from said support sections.

9. A surrogate card assembly according to claim 1 further comprising a face plate connected to said planar frame.

10. A surrogate card assembly according to claim 1 wherein said planar frame is formed of a single light-weight molded part, made from material approved by Underwriters Labs for use in Electrical Equipment, UL 476, and UL Safety Specifications 60950, UL94-VO Fire retardancy rating.

11. A surrogate card assembly according to claim 7, wherein said planar frame is formed of a single light-weight molded part, made from material approved by Underwriters Labs for use in Electrical Equipment, UL 476, and UL Safety Specifications 60950, UL94-VO Fire retardancy rating.

12. A surrogate card assembly according to claim 9, further comprising an electromagnetic compliance gasket lining that is attached to the chassis frame 10, that seals again face plate 115 when face plate is installed against chassis frame.
